(19) United States
(12) Patent Application Publication
(10) Pub. No.: US 2003/0181008 A1
(43) Pub. Date: Sep. 25, 2003

(54) Method for reducing particles and defects during flash memory fabrication

(76) Inventors: Weng-Hsing Huang, Hsin-Chu City (TW); Kent Kuohua Chang, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,139

(22) Filed: Mar. 25, 2002

(51) Int. Cl. H01L 21/336

(52) U.S. Cl. 438/257

(57) ABSTRACT

A method for reducing defects and particles during fabrication of a semiconductor device with an ONO film is disclosed. A substrate divided into a first region and a second region is provided. The first region has a plurality of floating gates and the second region has an oxide layer, a first polysilicon layer, and a second polysilicon layer. An oxide-nitride-oxide (ONO) film is formed over the floating gates and the second polysilicon layer. A patterned photoresist layer masking the first region is formed and a dry etch process is performed to remove the ONO layer, the first polysilicon layer, and the second polysilicon layer within the exposed second region. A series of cleaning steps are performed in a cascade manner.

### BACKGROUND OF INVENTION

1. Field of the Invention

The present invention relates to a method of fabricating a semiconductor device with an ONO film, and more particularly, to a method of fabricating a fresh memory with a cascade cleaning process.

2. Description of the Prior Art

Flash memory chips have advantages of being small and compact, as well as having an ability to maintain data without a requirement of electrical current. Thus, they are usually employed in portable electronic products, such as mobile phones or IC cards. In the production of a flash chip, at least one array area containing millions of flash memory cells and one peripheral area containing peripheral circuits for reading, writing and erasing the flash memory cells are pre-defined on the surface of a semiconductor wafer A memory cell comprises a pass transistor, usually a metal-oxide-semiconductor (MOS), and a storage capacitor, which comprises a top electrode, a bottom storage node, and a capacitor dielectric layer keeping the two electrodes at a pre-determined distance. As a voltage is held across the two electrodes, some electronics exist between the two electrodes. Most of the capacitor dielectric layers are made of oxide-nitride-oxide (ONO) films.

Please refer to FIG. 1 to FIG. 5. FIG. 1 to FIG. 5 are schematic diagrams of forming a fresh memory with an ONO film according to the prior art. Please refer to FIG. 1. First, a semiconductor 10 comprises a substrate 12, at least two field oxide layers 14 positioned on the substrate 12 to define two predetermined regions comprising a first region 13 for an array area, and a second region 15 for a peripheral area, a gate oxide layer 16 positioned on the first region 13, polysilicon (PL1) layers 18 positioned on gate oxide layers 16, and silicon nitride layers 20 positioned on the PL1 layers 18. Additionally, a plurality of buried drains/sources (BD/BS) 22 are positioned on the surface of the substrate 12.

Next, please refer to FIG. 2 with respect to FIG. 2. A deposition process is performed to form a dielectric layer 24 on the semiconductor wafer 10 covering the substrate 12 and the silicon nitride layer 20, wherein the top surface of the dielectric layer 24 is higher than that of the silicon nitride layer 20. A chemical mechanical polishing (CMP) process is then performed to planarize the surface. After that, the silicon nitride layer 20 is removed and a recess 17 is formed above the PL1 layer 18.

Next, please refer to FIG. 3. A second polysilicon layer 28 is formed on the semiconductor wafer 10 and filled into the recess 17, leading to the second polysilicon layer electrically connecting to the PL1 layer 18. A floating gate is formed by the two polysilicon layers 18 and 28. Then, an oxide-nitride-oxide (ONO) dielectric film 30 is formed on the surface of the semiconductor wafer 10. The ONO dielectric film 30 comprises a bottom oxide layer, a silicon nitride layer and a top oxide layer (not explicitly shown). According to the prior art, the thickness of the bottom oxide layer is about 43 angstroms. The thickness of the silicon nitride layer is about 62 angstroms. The thickness of the top oxide layer is about 60 angstroms.

Next, please refer to FIG. 4. A lithography process is performed to form a patterned photoresist layer 31 on the ONO layer 30 of the first region 13. Next, please refer to FIG. 5. A dry etching process is performed using the photoresist layer 31 as a hard mask. After etching the exposed second region, a sidewall 29 is exposed in the interface between the first region 13 and the second region 15. After that, another polysilicon (PL2) layer may be deposited thereon to form a capacitor structure in advance.

In the process according to the prior art, before forming the PL2 layer, there are usually some ONO fences, polymer after etch, and residual particles on the sidewall 29, as shown in the FIG. 5. These particles influence a follow-up process and lead to a decrease in the yield of the manufactory process. Therefore, a cleaning process is required after the photoresist layer 31 is removed. In the prior art, a cleaning process is performed by submersion in an SC-2 solution made of HCl, H₂O₂, and water with 1:1:6 at a temperature of 70° C., before going on to the follow-up process. However, for cleaning the polymer particles and ONO fences effectively, a long sinking time is required. It causes the SC-2 solution to corrode and damage the top oxide layer of the ONO film 30 (with a thickness lower than 60 angstroms), affecting the electrical performance of the ONO film. Therefore, a new method which can clean small particles, polymer after etch, and ONO fences effectively, without affecting the electrical performance of ONO films, is currently needed.

### SUMMARY OF INVENTION

It is therefore a primary objective of the present invention to provide a method of fabricating a semiconductor device with a cascade cleaning process to solve the above mentioned problem of residual particles. It is another objective of the present invention to compensate the oxide loss from BOE or dilute HF clean. The results show a great improvement of ONO fence and defect reduction.

In a preferred embodiment, the present invention provides a method of fabricating a semiconductor device with an ONO film comprising the following steps. First, a semiconductor wafer comprising a first region and a second region is provided. The first region comprises a plurality of storage nodes of bottom capacitors and the second region comprises an oxide layer, a first polysilicon layer, and a second polysilicon layer. Next, an oxide-nitride-oxide (ONO) film comprising a bottom oxide layer, a silicon nitride layer and a top oxide layer is formed in turn on the storage nodes and the second polysilicon layer. Then, a patterned photoresist layer, covering the first region only, is formed, and a dry etch process is performed to remove the exposed second region. After that, a cascade cleaning process is performed with the washing solutions BOE, SC-1 and SC-2 in turn.

It is an advantage of the present invention that the cascade cleaning process canclean the residual particles on the surface of a semiconductor wafer effectively. In addition, the thickness of the top oxide layers is increased to compensate the oxide loss caused by the cleaning process.

These and other objectives of the present invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 to FIG. 5 are schematic diagrams of forming a semiconductor device with an ONO film according to the prior art.

FIG. 6 to FIG. 12 are schematic diagrams of forming a semiconductor device with an ONO film according to the present invention.

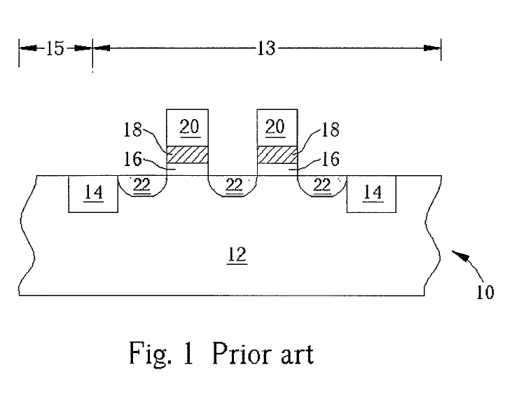

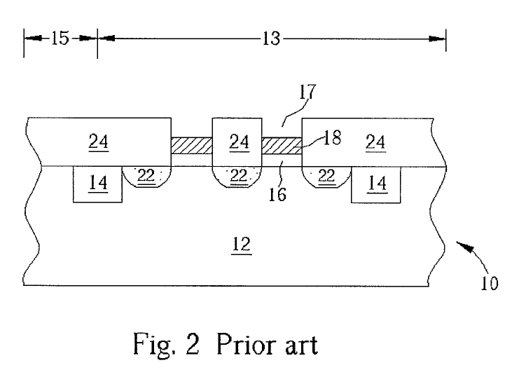

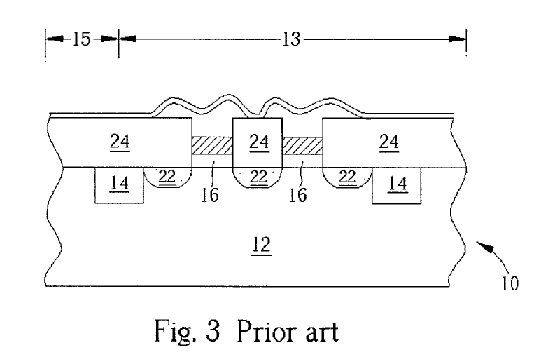

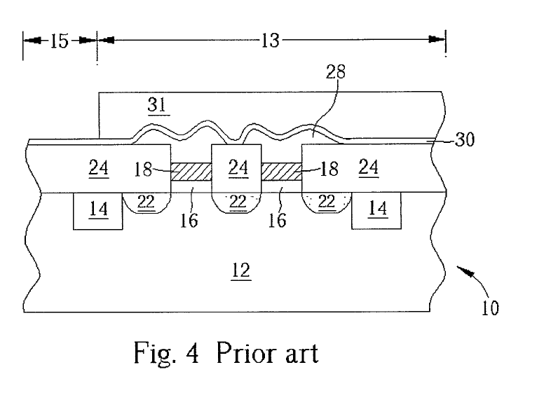

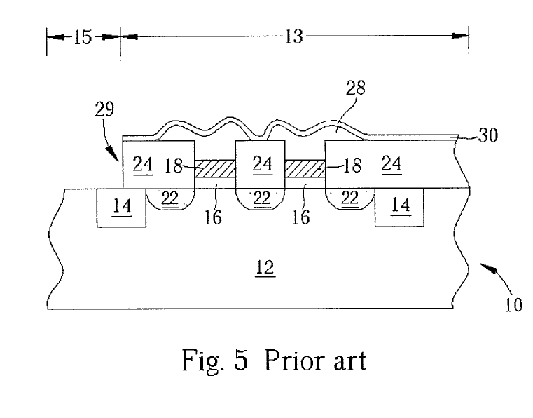

### DETAILED DESCRIPTION

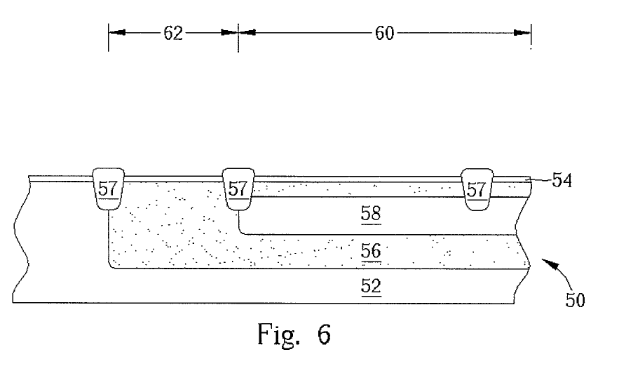

Please refer to Fig.6 to FIG. 12 of schematic diagrams of forming a semiconductor device with an ONO film according to the present invention. Please refer to FIG. 6. A semiconductor wafer 50 comprises a silicon substrate 52 comprising an N-well 56 and a P-well 58 in the N-well 56. The semiconductor wafer 50 further comprises a pad oxide layer 54 on the substrate 52 and a plurality of shallow trench isolation (STI) regions 57 which divide the semiconductor wafer 50 into a first region 60 predetermined for an array area and a second region 62 predetermined for a peripheral area.

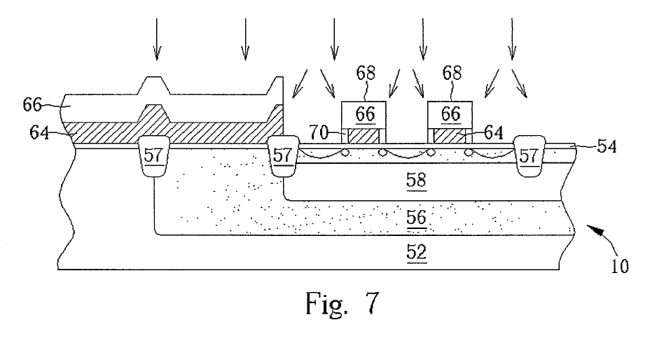

Next, please refer to FIG. 7. A chemical vapor deposition (CVD) process is performed to form a polysilicon layer 64 covering the pad oxide layer 54, followed by another CVD process to form a silicon nitride layer 66 on the polysilicon layer 64. In the preferred embodiment of the present invention, the thickness of the polysilicon layer 64 is in a range of 800 to 1200 angstroms and the thickness of the silicon nitride layer 66 is in a range of 1500 to 2500 angstroms.

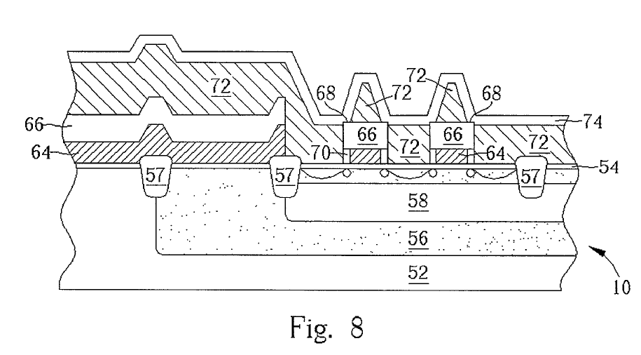

Next, a patterned photoresist layer (not shown) is formed on the surface of the semiconductor wafer 50 and a dry etch process is performed to remove the exposed area, leading to form two stacked gate structures 68. Then, a liner oxide layer 70 is formed adjacent to the gate structure 68. After that, an ion implantation process is performed to form a plurality of doped areas as buried sources or drains (BS/BD). In the preferred embodiment, the thickness of the liner oxide layer 70 is about 50 to 100 angstroms. Additionally, the above mentioned ion implantation process comprises two ion implantation processes. First, an arsenic ion implantation is performedin a direction nearly perpendicular to the surface of the semiconductor wafer 50 with an implanting energy of about 50 KeV and a dosage of about 1E14 to 1E16 (atom/cm²), leading to formation of the buried sources or drains. Then, a boronion implantation is performedin a direction with a tilt angle to the surface of the semiconductor wafer 50 with an implanting energy of about 70 KeV and a dosage of about 1E12 to 1E14 (atom/cm²) Next, please refer to FIG. 8. A high density plasma (HDP) chemical vapor deposition (CVD) is performed to form an oxide layer 72 with a thickness of about 1500 to 2500 angstroms covering the semiconductor wafer 50. Then, a wet etching process is performed to remove about 500 to 1000 angstroms of the oxide layer 72. After that, a protection layer 74 is deposited, wherein the protection layer 74 is made of silicon nitride with a thickness of about 400 angstroms.

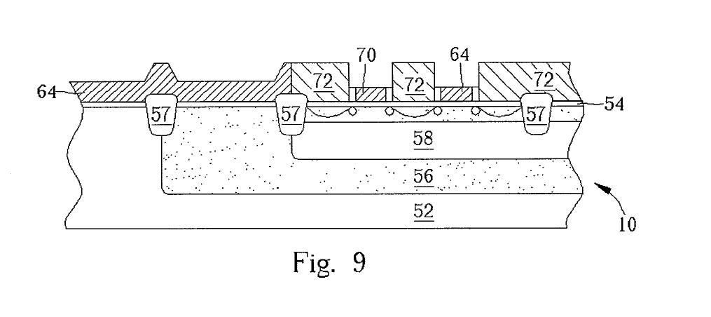

Next, please refer to FIG. 9. A chemical mechanical polish process is performed to remove parts of the protection layer 74 and the oxide layer 72. Then a wet etching process is performed with an etchant of hot phosphoric acid (H₃PO₃) to totally remove the protection layer 74 and the silicon nitride layer 66. After the wet etching process, the thickness of the oxide layer 72 is about 800 to 1800 angstroms.

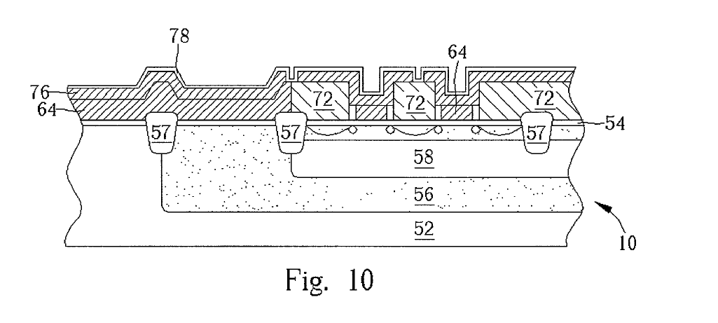

Next, please refer to FIG. 10. A chemical vapor deposition process is performed to form a polysilcon layer 76 with a thickness of about 300 to 800 angstroms on the surface of the semiconductor wafer 50. A phosphoric ion implantation is performed with an implanting energy of 20 KeV and a dosage of about 7E14 (atom/cm²). Then, a lithography process and an etching process are performed to form a recess. Additionally, the polysilicon layer 76 and the polysilicon layer 64 thereunder serve as a storage node of a memory cell.

Next, a bottom oxide layer, a silicon nitride layer and a top oxide layer are formed in turn. In the preferred embodiment of the present invention, the bottom oxide layer is formed by a method of high temperature oxidation (HTO) with a thickness of 43 angstroms. The silicon nitride layer is formed by a method of low pressure chemical vapor deposition with a thickness of 62 angstroms. The top oxide layer is formed by an HTO method with a thickness of 65 angstroms.

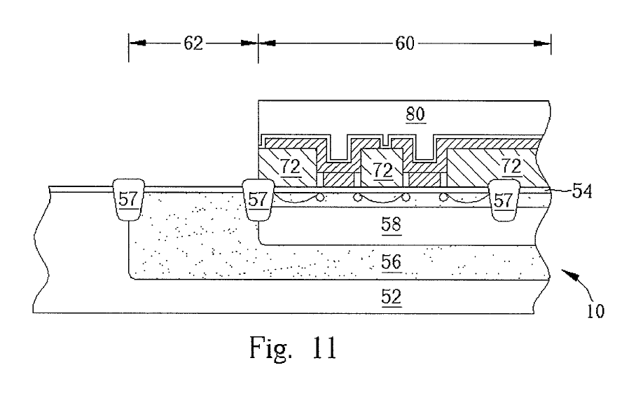

Next, please refer to FIG. 11. A lithography process is performed to form a patterned photoresist layer 80 covering the first region 60. Using the photoresist layer 80 as a hard mask, a dry etching process follows to remove exposed parts in the second region 62 comprising the ONO dielectric film 78, the polysilicon layer 76 and the polysilicon layer 64.

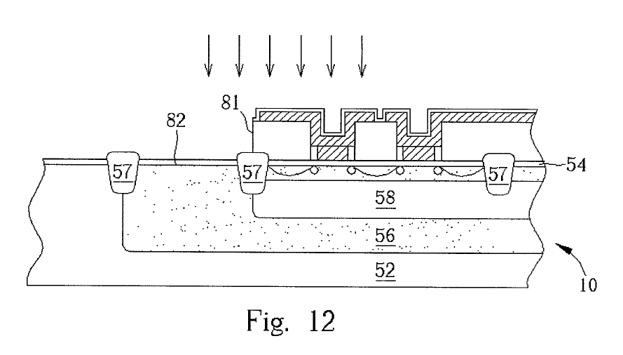

Next, please refer to FIG. 12. The photoresist layer 80 is removed. Since some residual particles attach on a sidewall 81 of the interface between the first region 60 and the second region 62, a cleaning process is needed after the photoresist layer 80 is removed. In the present invention, a cleaning process comprises a three steps cascade cleaning process. First, a buffer oxide etchant (BOE) is used in the cascade cleaning process. In this step of the cleaning process, the BOE removes the oxide layer 54 on the second region 62 and parts of top oxide layer of the ONO film, leading to the thickness of the top oxide layer decreasing from 65 to 60 angstroms. Then, an SC-1 solution comprising NH₄OH, H₂O₂ and water is used as an etchant for this cascade cleaning process. After that, an SC-2 solution comprising HCl, H₂O₂ and water is also used.

After the cleaning process, a thermal oxidation process is performed to form an oxide layer 82 on the first region 62 surface. Next, a chemical vapor deposition process is performed to form a polysilicon layer 82 covering the semiconductor wafer 50, serving as a top electrode. A capacitor structure consists of the top electrode, the ONO dielectric film 78 thereunder, and the bottom storage node, which comprises the polysilicon layers 64 and 76.

The cascade cleaning process used in the present invention is performed in a cascade washer, which includes a series of adjacent overflow washers. In use, fresh rinse liquid flows into the first, highest washer of the series. As the rinse liquid fills the first overflow washer and then discharges, it enters the second washer, which fills and then discharges into the third washer, and so forth. Wafers are first placed in the last washer of the series, which has the most contaminated rinse liquid supply from the cleaning of one or more preceding wafers or sets of wafers. The wafers are then sequentially repositioned into each adjacent washer until they are eventually washed in the first overflow washer, which has the freshest and cleanest water supply. Notice that there are many kinds of cascade washers in the industry. All material mentioned above is only an introduction. The cascade cleaning process in the present invention can be performed in all kinds of cascade washers without any limitation of specific machines.

In contrast to the prior art, being submersed in the SC-2 solution for a long time, the cascade cleaning in the present invention reduces the small particles, polymer after etch, and ONO fences effectively. Moreover, the thickness of the top oxide layer of the ONO film increases to 65 angstroms in the present invention. This modified thickness is about 10% more than the previous design and is used as a buffer layer to compensate the oxide loss in the BOE cleaning process. The results show great improvement of reliability of the follow-up process and reduce the random bit failure effectively.

Those skilled in the art will readily observe that numerous modifications and alterations of the device may be made while retaining the teaching of the invention. Accordingly, the above disclosure should be construed as limited only by the metes and bounds of the appended claims.

what is claimed is:

1. A method of fabricating a semiconductor device with an oxide-nitride-oxide (ONO) film, the method comprising:
providing a semiconductor wafer comprising a silicon substrate with a first region and a second region, wherein the first region comprises a plurality of capacitor storage nodes and the second region comprises a sacrificial layer, a first polysilicon layer and a second polysilicon layer;
sequentially forming a bottom oxide layer, a silicon nitride layer and a top oxide layer over the plurality of capacitor storage nodes and over the second polysilicon layer within the second region, wherein the ONO film consists of the bottom oxide layer, the silicon nitride layer and the top oxide layer, and the top
oxide layer has a thickness of about 65 angstroms;
masking the first region with a photoresist layer;
dry etching unmasked portions of the ONO film, the second polysilicon layer and the first polysilicon layer within the second region;
removing the photoresist layer;
cascade cleaning the semiconductor wafer with a buffer oxide etchant (BOE) to remove the sacrificial layer within the second region and a portion of the top oxide layer;
cascade cleaning the semiconductor wafer with a SC-1 solution; and
cascade cleaning the semiconductor wafer with a SC-2 solution.

2. The method of claim 1 wherein the first and the second regions are isolated by a shallow trench isolation (STI) region.

3. The method of claim 1 wherein each of the capacitor storage nodes is composed of two layers of polysilicon.

4. The method of claim 1 wherein after cascade cleaning the semiconductor wafer with the SC-2 solution, the method further comprises:
performing a thermal process to form a silicon oxide layer over the silicon substrate within the first region; and
concurrently depositing a third polysilicon layer over the first and the second regions.

5. The method of claim 1 wherein the SC-1 solution comprises NH₄OH, H₂O₂ and H₂O.

6. The method of claim 1 wherein the SC-2 solution comprises HCl, H₂O₂ and H₂O.

7. The method of claim 1 wherein after cascade cleaning the semiconductor wafer with the BOE, the top oxide layer has a remaining thickness of about 60 angstroms.

8. The method of claim 1 wherein the bottom oxide layer has a thickness of about 43 angstroms and the silicon nitride layer has a thickness of about 62 angstroms.

9. A method for reducing particles and defects, the method comprising:
providing a semiconductor wafer comprising a silicon substrate, the silicon substrate having a first region and a second region, wherein an oxide-nitride-oxide (ONO) film covers the first and the second regions, and within the second region underneath the ONO film there are a sacrificial layer, a first polysilicon layer and a second polysilicon layer;
masking the first region with a photoresist layer;
dry etching unmasked portions of the ONO film, the second polysilicon layer, and the first polysilicon layer within the second region;
removing the photoresist layer;
cascade cleaning the semiconductor wafer with a buffer oxide etchant (BOE) to remove the sacrificial layer within the second region;
cascade cleaning the semiconductor wafer with an SC-1 solution; and
cascade cleaning the semiconductor wafer with an SC-2 solution.

10. The method of claim 9 wherein the first region and the second region are isolated by a shallow trench isolation (STI) region.

11. The method of claim 9 wherein the semiconductor wafer further comprises a plurality of capacitor storage nodes within the first region, and the ONO film is formed on the plurality of capacitor storage nodes.

12. The method of claim 11 wherein each of the capacitor storage nodes is composed of two layers of polysilicon.

13. The method of claim 9 wherein after cascade cleaning the semiconductor wafer with the SC-2 solution, the method further comprises:
performing a thermal process to form a silicon oxide layer over the silicon substrate within the first region; and
concurrently depositing a third polysilicon layer over the first region and the second region.

14. The method of claim 9 wherein the SC-1 solution comprises NH₄OH, H₂O₂ and H₂O.

15. The method of claim 9 wherein the SC-2 solution comprises HCl, H₂O₂ and H₂O.

16. A method for reducing defects and particles during fabrication of a semiconductor device with an ONO film, comprising:
providing a substrate divided into a first region and a second region, wherein
the first region has a plurality of floating gates and the second region has an oxide layer, a first polysilicon layer, and a second polysilicon layer;
forming an oxide-nitride-oxide (ONO) film over the floating gates and the second polysilicon layer;
forming a patterned photoresist layer masking the first region;
performing a dry etch process to remove the ONO layer, the first polysilicon layer, and the second polysilicon layer within the exposed second region; and
performing a series of cleaning steps in a cascade manner.

17. The method of claim 16 wherein the cleaning steps in a cascade manner comprise:
cascade cleaning the substrate with a buffer oxide etchant (BOE);
cascade cleaning the substrate with an SC-1 solution; and
cascade cleaning the substrate with an SC-2 solution.

18. The method of claim 17 wherein the SC-1 solution comprises NH₄OH, H₂O₂ and H₂O.

19. The method of claim 17 wherein the SC-2 solution comprises HCl, H₂O₂ and H₂O.
